(19) United States
(12) Patent Application Publication
(10) Pub. No.: US 2017/0117460 A1
(43) Pub. Date: Apr. 27, 2017

(54) METHOD OF MANUFACTURING MAGNETORESISTIVE ELEMENT AND SYSTEM FOR MANUFACTURING MAGNETORESISTIVE ELEMENT

(71) Applicant: TOKYO ELECTRON LIMITED, Tokyo (JP)

(72) Inventor: Kenichi Imakita, Nirasaki City (JP)

(73) Assignee: TOKYO ELECTRON LIMITED, Tokyo (JP)

(21) Appl. No.: 15/297,467

(22) Filed: Oct. 19, 2016

(30) Foreign Application Priority Data
Oct. 22, 2015 (JP) 2015-207745

(51) Int. Cl. H01L 43/12; H01L 43/02; H01L 43/10

(52) U.S. Cl. CPC H01L 43/12; H01L 43/10; H01L 43/02

(57) ABSTRACT

Manufacturing a magnetoresistive element excellent in RA and MR ratio is enabled. A method of manufacturing a magnetoresistive element of an embodiment includes forming a first laminate constituting a lower electrode on a base substrate, forming a second laminate which is a magnetoresistive effect laminate on the first laminate, and forming an upper electrode on the second laminate. The step of forming a first laminate includes forming a metal layer on the base substrate, forming a conductive amorphous layer on the metal layer, and performing ion etching on the conductive amorphous layer.

### CROSS-REFERENCE TO RELATED APPLICATIONS

This application is based on and claims the benefit of priority from Japanese Patent Application No. 2015-207745 filed on Oct. 22, 2015, the entire contents of which is incorporated herein by reference.

### BACKGROUND

Field

Exemplary embodiments of the present disclosure relate to a method of manufacturing a magnetoresistive element and a system for manufacturing a magnetoresistive element.

Related Background Art

A magnetoresistive element is used in a device such as a magnetic head or a magnetoresistive random access memory (MRAM). The magnetoresistive element includes a lower electrode, an upper electrode, and a magnetoresistive effect laminate provided between the lower electrode and the upper electrode. In the manufacturing of such a magnetoresistive element, the lower electrode is formed on a base substrate, and a plurality of layers configuring the magnetoresistive effect laminate are next formed in order. Thereafter, the upper electrode is formed on the magnetoresistive effect laminate.

In general, a lower electrode includes a metal layer having a large film thickness, and the metal layer has a large surface roughness immediately after the formation thereof. That is, the surface of the metal layer has large undulations. Since a magnetoresistive effect laminate is formed on the lower electrode including such a metal layer, each layer of the magnetoresistive effect laminate also has large undulations. In a case where each layer of the magnetoresistive effect laminate has large undulations, a contact area between adjacent layers in the magnetoresistive effect laminate becomes larger. In addition, grain boundaries having a large disorder at the atomic level occur in the magnetoresistive effect laminate. In the manufacturing of the magnetoresistive element, heat treatment is generally performed on the magnetoresistive element, but after the heat treatment, the migration of atoms between layers occurs due to the large contact area, and thus the large grain boundaries, and the like, the characteristics of a magnetoresistive element such as resistance area product (RA) and MR ratio deteriorate.

In order to cope with a problem of such a deterioration in the characteristics of a magnetoresistive element, Japanese Patent Application Laid-Open Publication No. 2009-158089 discloses that a plasma processing is performed on a layer constituting a magnetoresistive element to planarize the surface of the layer.

The undulations of each layer of the magnetoresistive effect laminate described above are caused by the undulations of the lower electrode. Therefore, it is necessary to reduce the undulations of the lower electrode. The metal layer configuring the lower electrode is generally formed by sputtering, and thus is a polycrystalline film including a large number of crystal grains and crystal grain boundaries. In a case where such a metal layer is etched by plasma processing, protruding portions of the metal layer, for example, the tips of the crystal grains are etched in the initial stage of etching, and the undulations in the surface of the metal layer are reduced. However, in a case where the metal layer is further etched for further planarization, portions having a low atom density, that is, portions in which the crystal grain boundaries are present is preferentially etched. Therefore, in etching based on plasma processing, the undulations in the surface of the metal layer cannot be sufficiently reduced. Hence, it is not possible to obtain a magnetoresistive element excellent in RA and MR ratio.

### SUMMARY

In an aspect, a method of manufacturing a magnetoresistive element is provided. The method includes forming a first laminate constituting a lower electrode of the magnetoresistive element on a base substrate, forming a second laminate which is a magnetoresistive effect laminate of the magnetoresistive element on the first laminate, and forming an upper electrode of the magnetoresistive element on the second laminate. The step of forming a first laminate includes forming a metal layer on the base substrate, forming a conductive amorphous layer on the metal layer, and performing ion etching on the conductive amorphous layer.

In another aspect, a system for manufacturing a magnetoresistive element is provided. The manufacturing system includes a transfer module, a plurality of process modules, and a control unit. The transfer module includes a depressurizable container, and a transfer device provided within the container for transferring a substrate. The plurality of process modules are connected to the transfer module. The process modules are modules for forming a metal layer, forming a conductive amorphous layer, ion etching, forming a magnetoresistive effect laminate, and forming an upper electrode. The control unit is configured to control the transfer module and the plurality of process modules. The control unit controls the transfer device and the plurality of process modules to form the metal layer on a base substrate, form the conductive amorphous layer on the metal layer, perform ion etching on the conductive amorphous layer, form the magnetoresistive effect laminate on the conductive amorphous layer, and form the upper electrode on the magnetoresistive effect laminate. In the manufacturing system, the formation of each layer of the magnetoresistive element and the planarization of the conductive amorphous layer can be performed under a depressurized environment. Therefore, an apparatus (for example, a chemical mechanical polishing apparatus) that performs a planarization process under an atmospheric pressure environment is not required, and thus it is possible to achieve a reduction in the number of steps.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a flow diagram illustrating a method of manufacturing a magnetoresistive element according to an exemplary embodiment.

FIGS. 2A and 2B are enlarged cross-sectional views of an exemplary intermediate product which is produced in the manufacturing method shown in FIG. 1.

FIG. 3 is a diagram illustrating ion etching in the manufacturing method shown in FIG. 1.

FIGS. 4A and 4B are enlarged cross-sectional views of an exemplary intermediate product which is produced in the manufacturing method shown in FIG. 1.

FIG. 5 is a diagram illustrating ion etching in the manufacturing method shown in FIG. 1.

FIG. 6 is an enlarged cross-sectional view of an exemplary intermediate product which is produced in the manufacturing method shown in FIG. 1.

FIG. 7 is an enlarged cross-sectional view of an exemplary intermediate product which is produced in the manufacturing method shown in FIG. 1.

FIG. 8 is an enlarged cross-sectional view of an exemplary final product produced in the manufacturing method shown in FIG. 1.

FIG. 9 is a diagram schematically illustrating a system for manufacturing a magnetoresistive element according to an exemplary embodiment.

FIG. 10 is a diagram schematically illustrating an example of a sputtering apparatus capable of being used as a process module of the manufacturing system shown in FIG. 9.

FIGS. 11A and 11B are plan views illustrating a shutter of the sputtering apparatus when seen from the stage side.

### DETAILED DESCRIPTION

In the following detailed description, reference is made to the accompanying drawings, which form a part hereof. The exemplary embodiments described in the detailed description, drawing, and claims are not meant to be limiting. Other exemplary embodiments may be utilized, and other changes may be made, without departing from the spirit or scope of the subject matter presented here.

In an aspect, a method of manufacturing a magnetoresistive element is provided. The method includes forming a first laminate constituting a lower electrode of the magnetoresistive element on a base substrate, forming a second laminate which is a magnetoresistive effect laminate of the magnetoresistive element on the first laminate, and forming an upper electrode of the magnetoresistive element on the second laminate. The step of forming a first laminate includes forming a metal layer on the base substrate, forming a conductive amorphous layer on the metal layer, and performing ion etching on the conductive amorphous layer.

In the method, the conductive amorphous layer is formed on the metal layer of the lower electrode. In contrast to a polycrystalline film, the crystal grains and the crystal grain boundaries are not substantially present in the conductive amorphous layer. Therefore, the undulations in the surface of the conductive amorphous layer are reduced by ion etching. Since the magnetoresistive effect laminate, that is, the second laminate is formed on the lower electrode including the conductive amorphous layer, a magnetoresistive effect laminate having small undulations in each layer is obtained, and the generation of grain boundaries is suppressed. As a result, a magnetoresistive element excellent in the RA and MR ratio is provided.

In an exemplary embodiment, the step of forming a first laminate may further include performing ion etching on the metal layer before execution of the step of forming a conductive amorphous layer.

In an exemplary embodiment, the conductive amorphous layer may be made of an alloy containing three elements or four elements, and may contain at least one element of boron (B), carbon (C), nitrogen (N), magnesium (Mg), aluminum (Al), silicon (Si), and titanium (Ti), and at least one element of copper (Cu), zinc (Zn), zirconium (Zr), niobium (Nb), molybdenum (Mo), hafnium (Hf), tantalum (Ta), and tungsten (W). In an exemplary embodiment, the conductive amorphous layer may be made of CuZrAl, CuTiAl, TaZrN, or TiZrNbB.

In an exemplary embodiment, the metal layer and the conductive amorphous layer may be formed by sputtering.

In another aspect, a system for manufacturing a magnetoresistive element is provided. The manufacturing system includes a transfer module, a plurality of process modules, and a control unit. The transfer module includes a depressurizable container, and a transfer device provided within the container for transferring a substrate.

The plurality of process modules are connected to the transfer module. The process modules are modules for forming a metal layer, forming a conductive amorphous layer, ion etching, forming a magnetoresistive effect laminate, and forming an upper electrode. The control unit is configured to control the transfer module and the plurality of process modules. The control unit controls the transfer device and the plurality of process modules to form the metal layer on a base substrate, form the conductive amorphous layer on the metal layer, perform ion etching on the conductive amorphous layer, form the magnetoresistive effect laminate on the conductive amorphous layer, and form the upper electrode on the magnetoresistive effect laminate. In the manufacturing system, the formation of each layer of the magnetoresistive element and the planarization of the conductive amorphous layer can be performed under a depressurized environment. Therefore, an apparatus (for example, a chemical mechanical polishing apparatus) that performs a planarization process under an atmospheric pressure environment is not required, and thus it is possible to achieve a reduction in the number of steps.

In an exemplary embodiment, the control unit may further control one process module of the plurality of process modules to perform ion etching on the metal layer before the conductive amorphous layer is formed.

In an exemplary embodiment, the plurality of process modules may include one or more sputtering apparatuses for forming the metal layer and forming the conductive amorphous layer.

Hereinafter, various embodiments will be described in detail with reference to the accompanying drawings. In the respective drawings, the same or equivalent portions are denoted by the same reference numerals or signs.

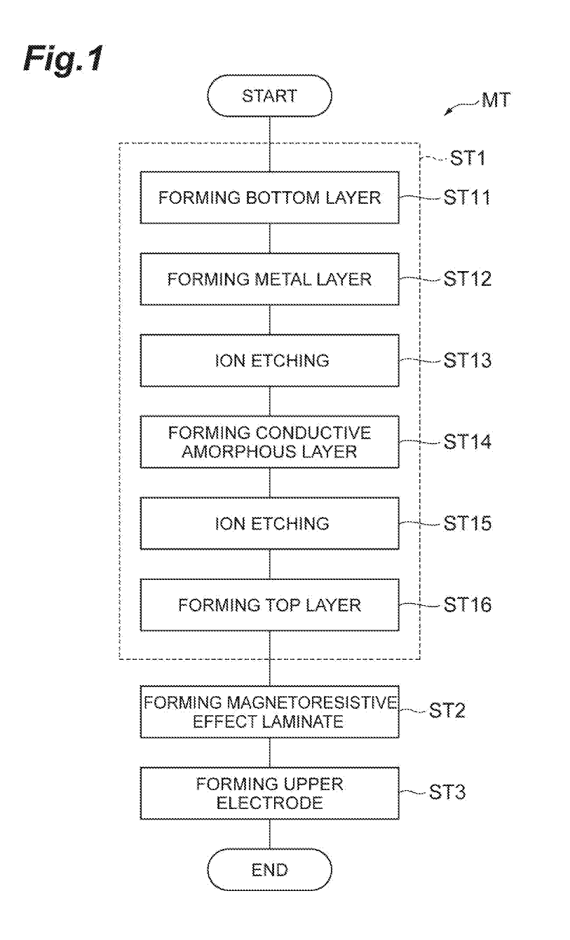

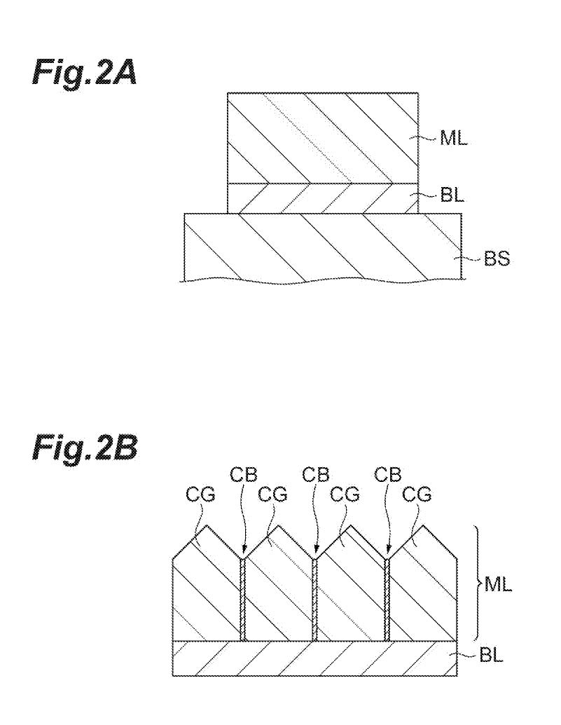

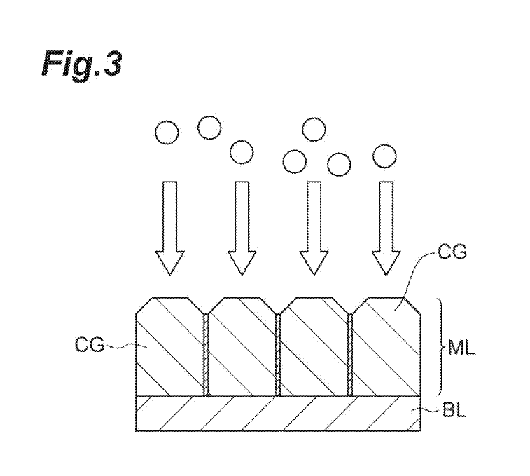

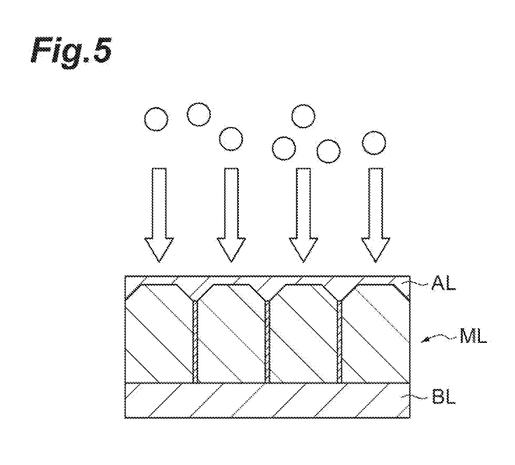

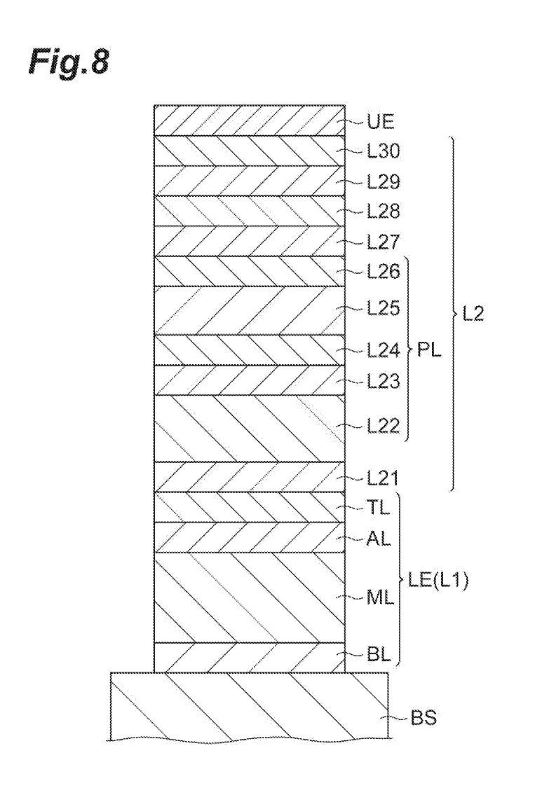

FIG. 1 is a flow diagram illustrating a method of manufacturing a magnetoresistive element according to an exemplary embodiment. FIGS. 2A, 2B, 4A, 4B and 6 to 7 are enlarged cross-sectional views illustrating a portion of an exemplary intermediate product which is produced in the manufacturing method shown in FIG. 1. FIG. 8 is an enlarged cross-sectional view illustrating a portion of an exemplary final product which is produced in the manufacturing method shown in FIG. 1. FIGS. 3 and 5 are diagrams illustrating ion etching in the manufacturing method shown in FIG. 1.

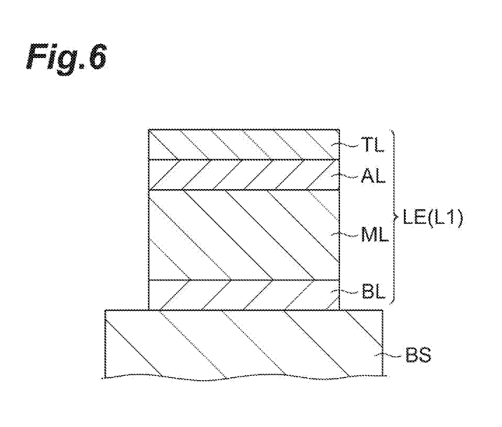

A manufacturing method MT shown in FIG. 1 starts with step ST1. In step ST1, as shown in FIG. 6, a lower electrode LE of a magnetoresistive element is formed on a base substrate BS. The lower electrode LE is configured by a first laminate L1. The first laminate L1 includes a plurality of layers. Specifically, the lower electrode LE includes a metal layer ML and a conductive amorphous layer AL. In one example, the lower electrode LE may further include a bottom layer BL and a top layer TL. In a case where the lower electrode LE of this example is formed, step ST1 of the manufacturing method MT includes step ST11 to step ST16 as shown in FIG. 1.

In step ST11, a bottom layer BL is formed on the base substrate BS. The bottom layer BL is made of, for example, tantalum (Ta). The bottom layer BL is formed by, for example, sputtering. In subsequent step ST12, the metal layer ML is formed on the base substrate BS with the bottom layer BL interposed therebetween. The metal layer ML is made of, for example, ruthenium (Ru). The metal layer ML can have a film thickness of, for example, 50 nm. This metal layer ML is formed by, for example, sputtering. An intermediate product shown in FIG. 2A is obtained by the execution of step ST12.

As shown in FIG. 2B, the metal layer ML formed in step ST12 is a polycrystalline film including a large number of crystal grains CG and crystal grain boundaries CB, and has undulations in the surface thereof. In the manufacturing method MT of an exemplary embodiment, step ST13 is executed to reduce such undulations in the surface of the metal layer ML. In step ST13, ion etching is performed on the metal layer ML. In the ion etching of step ST13, as shown in FIG. 3, the surface of the metal layer ML is irradiated with rare gas ions (for example, Ar ions). In FIG. 3, circles indicate rare gas ions. When the surface of the metal layer ML is irradiated with the rare gas ions, the tips of the crystal grains CG are removed, and the undulations in the surface of the metal layer ML are reduced. The ion etching of step ST13 may be plasma etching, or may be gas cluster ion beam etching.

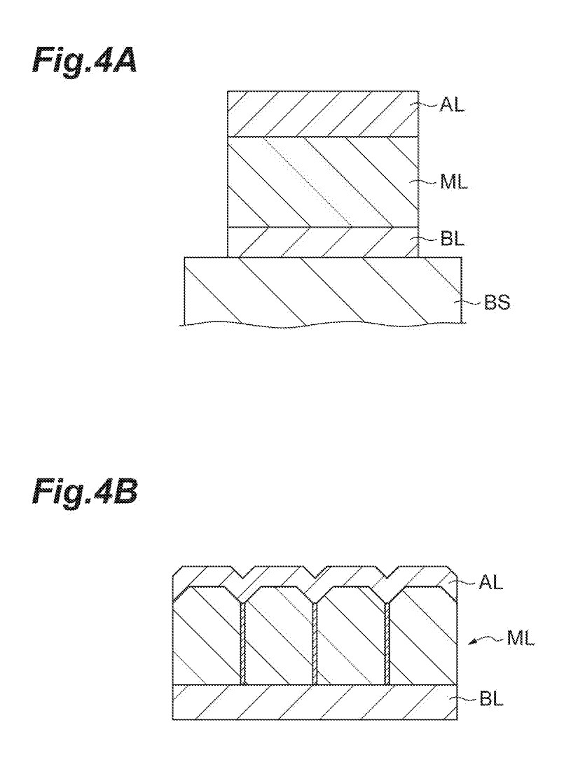

In subsequent step ST14, a conductive amorphous layer AL is formed on the metal layer ML. The conductive amorphous layer AL may be made of an alloy containing three elements or four elements, and may contain at least one element of boron (B), carbon (C), nitrogen (N), magnesium (Mg), aluminum (Al), silicon (Si), and titanium (Ti), and at least one element of copper (Cu), zinc (Zn), zirconium (Zr), niobium (Nb), molybdenum (Mo), hafnium (Hf), tantalum (Ta), and tungsten (W). For example, the conductive amorphous layer AL is made of CuZrAl, CuTiAl, TaZrN, or TaZrNbB. The conductive amorphous layer AL is formed by, for example, sputtering. An intermediate product shown in FIG. 4A is obtained by the execution of step ST14.

As shown in FIG. 4B, in a state after the execution of step ST14, the conductive amorphous layer AL has undulations on which the undulations of the metal layer ML are reflected. In order to reduce the undulations in the surface of the conductive amorphous layer AL, step ST15 is next executed. In step ST15, ion etching is performed on the conductive amorphous layer AL. In the ion etching of step ST15, as shown in FIG. 5, the surface of the conductive amorphous layer AL is irradiated with rare gas ions (for example, Ar ions). In FIG. 5, circles indicate rare gas ions. In contrast to a polycrystalline film such as the metal layer ML, crystal grains and crystal grain boundaries are not substantially present in the conductive amorphous layer AL. Therefore, when the surface of the conductive amorphous layer AL is irradiated with the rare gas ions, initially, portions protruding in the entire region of the surface of the conductive amorphous layer AL are preferentially etched, and then the entirety of the surface is substantially uniformly etched. As a result, the undulations on the surface of the conductive amorphous layer AL are reduced. That is, the surface of the conductive amorphous layer AL is planarized. The ion etching of step ST15 may be plasma etching, or may be gas cluster ion beam etching.

In subsequent step ST16, the top layer TL is formed on the conductive amorphous layer AL. The top layer TL is made of, for example, tantalum (Ta). The top layer TL is formed by, for example, sputtering. As shown in FIG. 6, an intermediate product including the lower electrode LE is obtained by the execution of step ST16.

In subsequent step ST2, a second laminate L2 which is a magnetoresistive element laminate is formed on the lower electrode LE. In an example, the second laminate L2 includes a first layer L21 to a tenth layer L30. The first layer L21 is made of, for example, platinum (Pt). The second layer L22 to the sixth layer L26 configures a pinning layer PL. For example, the second layer L22 and the fifth layer L25 may be a multilayer film including a cobalt (Co) film and a Pt film. The third layer L23 may be made of Co, the fourth layer L24 may be made of Ru, and the sixth layer L26 may be made of Co. The seventh layer L27 is made of, for example, Ta.

The eighth layer L28 configures a reference layer, and the tenth layer L30 configures a free layer. The eighth layer L28 and the tenth layer L30 are made of, for example, CoFeB, that is, Co, iron (Fe), and boron (B). The ninth layer L29 is an insulating layer provided between the eighth layer L28 and the tenth layer L30, and configures a tunnel barrier layer. The ninth layer L29 is made of, for example, MgO, that is, a magnesium oxide.

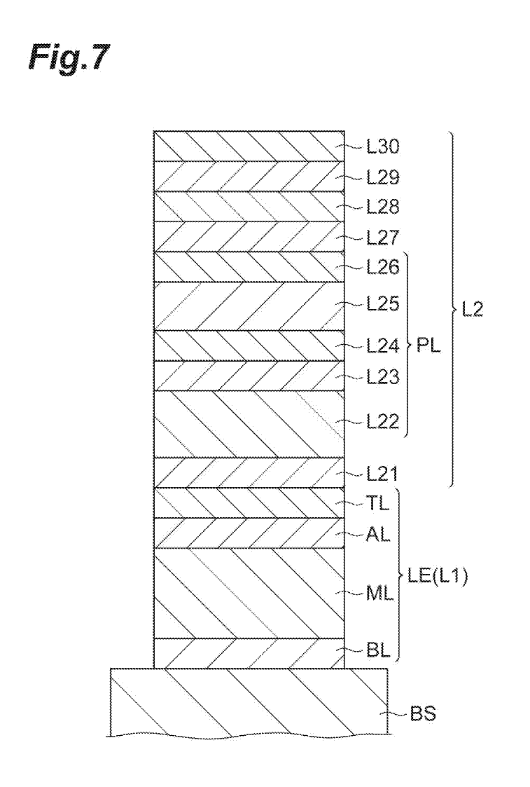

A plurality of layers forming the second laminate L2, that is, the first layer L21 to the tenth layer L30 are formed on the lower electrode LE in order. The plurality of layers forming the second laminate L2 may be formed by, for example, sputtering. The ninth layer L29 may be formed by sputtering an insulator. Alternatively, the ninth layer L29 may be formed by forming a metal film by sputtering a metal material (for example, Mg), and oxidizing the metal film. As shown in FIG. 7, an intermediate product including the lower electrode LE and the second laminate L2, that is, a magnetoresistive effect laminate is obtained by the execution of step ST2.

In subsequent step ST3, an upper electrode UE is formed on the second laminate L2. The upper electrode UE may be formed with a multilayer film including, for example, a Ta film and a Ru film. The upper electrode UE is formed by, for example, sputtering. A final product shown in FIG. 8, that is, a magnetoresistive element is obtained by step ST3.

In this manufacturing method MT, as described above, the conductive amorphous layer AL is formed on the metal layer ML of the lower electrode LE. In contrast to a polycrystalline film, crystal grains and crystal grain boundaries are not substantially present in the conductive amorphous layer AL. Therefore, the undulations in the surface of the conductive amorphous layer AL are reduced by ion etching. Since a magnetoresistive effect laminate, that is, the second laminate L2 is formed on the lower electrode LE including this conductive amorphous layer AL, a magnetoresistive effect laminate having small undulations in each layer is obtained, and the generation of grain boundaries is suppressed. As a result, a magnetoresistive element excellent in the RA and MR ratio is provided.

The magnetoresistive element shown in FIG. 8 is an element having a magnetic tunnel junction (MTJ) structure, and is an element used in a magnetoresistive random access memory. However, the magnetoresistive element manufactured by the manufacturing method MT is not limited to the magnetoresistive element having a MTJ structure, and may be a magnetoresistive element having a spin-valve structure. In addition, the magnetoresistive element manufactured by the manufacturing method MT is not limited to the element used in a magnetoresistive random access memory, and may be an element used in a magnetic head.

In addition, the first layer L21 to the seventh layer L27 may be formed between the tenth layer L30 and the upper electrode UE in a reverse lamination sequence to the lamination sequence shown in FIG. 8. In this case, the tenth layer L30 serves as a reference layer, and the eighth layer L28 serves as a free layer.

In addition, in the manufacturing method MT shown in FIG. 1, the conductive amorphous layer AL is formed on the metal layer ML, but the conductive amorphous layer AL may be formed on the top layer TL. In addition, step ST13, that is, ion etching performed on the metal layer ML may be omitted from the manufacturing method MT shown in FIG. 1.

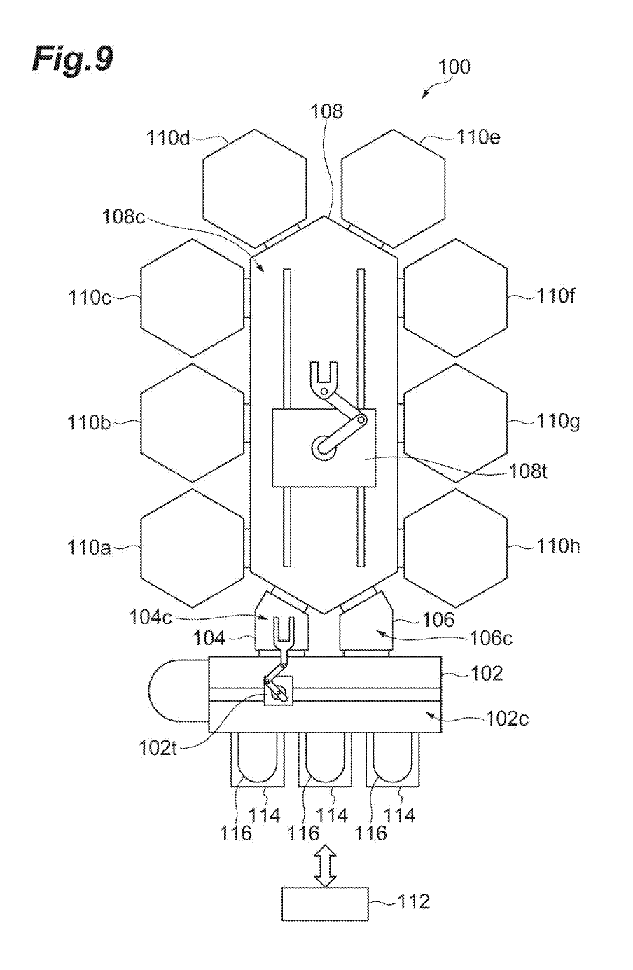

Hereinafter, a manufacturing system capable of being used in the execution of the manufacturing method MT will be described. FIG. 9 is a diagram schematically illustrating a system for manufacturing a magnetoresistive element according to an exemplary embodiment. A manufacturing system 100 shown in FIG. 9 includes a loader module 102, load lock modules 104 and 106, a transfer module 108, a plurality of process modules 110a to 110h, and a control unit 112. It should be noted that the number of process modules is eight in the manufacturing system 100 shown in FIG. 9, but may be an arbitrary number.

The loader module 102 is an apparatus that transfers a substrate under an atmospheric pressure environment. A plurality of tables 114 are attached to the loader module 102. A front opening unified pod (FOUP) 116 capable of receiving a plurality of substrates is mounted on each of the plurality of tables 114.

The loader module 102 includes a transfer device 102t in a transfer chamber 102c located in an inside thereof. The transfer device 102t may include a robot arm for holding a substrate and transferring the substrate. The load lock module 104 and the load lock module 106 are connected to the loader module 102. The transfer device 102t transfers a substrate between the FOUP 116 and the load lock module 104, or between the FOUP 116 and the load lock module 106.

The load lock module 104 and the load lock module 106 provide a chamber 104c and a chamber 106c for preliminary depressurization, respectively. The transfer module 108 is connected to the load lock module 104 and the load lock module 106. The transfer module 108 provides a depressurizable transfer chamber 108c, and includes a transfer device 108t in the transfer chamber 108c. The transfer device 108t may include a robot arm for holding a substrate and transferring the substrate. The plurality of process modules 110a to 110h are connected to the transfer module 108. The transfer device 108t of the transfer module 108 transfers a substrate between any of the load lock module 104 and load lock module 106 and any of the plurality of process modules 110a to 110h, and between two arbitrary process modules out of the plurality of process modules 110a to 110h.

The plurality of process modules 110a to 110h includes several apparatuses for forming the metal layer ML, forming the conductive amorphous layer AL, ion etching, forming a magnetoresistive effect laminate, that is, the second laminate, and forming the upper electrode UE. In addition, the plurality of process modules 110a to 110h includes one or more apparatuses for forming the bottom layer BL and the top layer TL of the lower electrode LE. In an embodiment, the plurality of process modules 110a to 110h includes a plurality of sputtering apparatuses. Each of the plurality of sputtering apparatuses is configured to perform the film formation of one or more target substances. In a case where the manufacturing system 100 is configured to manufacture the magnetoresistive element shown in FIG. 8, each of the plurality of sputtering apparatuses includes one or more corresponding targets out of a Ta target, a Ru target, a Pt target, a Co target, a CoFeB target, a magnesium oxide target, and a target for the conductive amorphous layer AL, that is, a target containing the three elements or the four elements described above. In an example, each of the plurality of sputtering apparatuses may include four targets, and may be a sputtering apparatus that sputters a constitutive substance of a target selected from the four targets.

It should be noted that one of the plurality of sputtering apparatuses may include a Mg target rather than a MgO target. In this case, one of the plurality of process modules 110a to 110h may be an oxidation treatment apparatus for oxidizing a Mg film. The oxidation treatment apparatus may be an apparatus that heats the Mg film under an oxygen atmosphere, or may be a plasma processing apparatus that generates plasma of an oxygen gas. The plasma processing apparatus may be an arbitrary plasma processing apparatus such as a capacitive coupling-type plasma processing apparatus, an inductive coupling-type plasma processing apparatus, or a plasma processing apparatus that generates plasma using a surface wave, such as a microwave.

In addition, one of the plurality of process modules 110a to 110h may be an ion etching apparatus for ion etching in the above-described manufacturing method MT. The ion etching apparatus may be a plasma processing apparatus that generates plasma of a rare gas. Such a plasma processing apparatus may be an arbitrary plasma processing apparatus such as a capacitive coupling-type plasma processing apparatus, an inductive coupling-type plasma processing apparatus, or a plasma processing apparatus that generates plasma using a surface wave, such as a microwave. Alternatively, the ion etching apparatus may be a gas cluster ion beam apparatus that generates an ion beam of a rare gas. Alternatively, one of the plurality of sputtering apparatuses may be used as an ion etching apparatus. In this case, plasma of a rare gas is generated in one of the plurality of sputtering apparatuses.

In addition, in an embodiment, the plurality of process modules 110a to 110h may include a heat treatment apparatus for heating a magnetoresistive element. Such a heat treatment apparatus is used, for example, in order to heat the magnetoresistive element shown in FIG. 8 after production thereof.

The control unit 112 is configured to control the transfer module 108 and the plurality of process modules 110a to 110h. In addition, the control unit 112 is configured to further control the loader module 102. The control unit 112 may be, for example, a computer device including a processor and a storage device such as a memory. The storage device stores a program for controlling each unit of the manufacturing system 100 and recipe data for executing the above-described manufacturing method MT in the manufacturing system 100. The processor operates in accordance with the program and the recipe data stored in the storage device, and outputs a control signal for controlling each unit of the manufacturing system 100 to the each unit.

In the execution of the manufacturing method MT, the control unit 112 controls the transfer device 102t of the loader module 102 to transfer the base substrate BS from the FOUP 116 to any of the load lock module 104 or the load lock module 106. Next, the control unit 112 controls the transfer device 108t of the transfer module 108 to transfer the base substrate BS transferred into any of the load lock module 104 or the load lock module 106 to a sputtering apparatus having a target for the bottom layer BL. The control unit 112 then controls the sputtering apparatus to form the bottom layer BL on the base substrate BS.

Next, the control unit 112 controls the transfer device 108t of the transfer module 108 to transfer an intermediate product including the base substrate BS and the bottom layer BL to a sputtering apparatus having a target for the metal layer ML. It should be noted that in a case where the target for the bottom layer BL and the target for the metal layer ML are provided in one sputtering apparatus, such transfer is not required. The control unit 112 controls the sputtering apparatus to form the metal layer ML on the bottom layer BL.

In an embodiment, the control unit 112 controls the transfer device 108t of the transfer module 108 to transfer an intermediate product including the base substrate BS, the bottom layer BL, and the metal layer ML to a process module for performing ion etching on the metal layer ML. It should be noted that in a case where this process module is a sputtering apparatus having the target for the metal layer ML, the transfer is not required. The control unit 112 controls the process module to perform ion etching on the metal layer ML.

Next, the control unit 112 controls the transfer device 108t of the transfer module 108 to transfer an intermediate product after ion etching of the metal layer ML to a sputtering apparatus having the target for the conductive amorphous layer AL. It should be noted that in a case where this sputtering apparatus is the same as the process module for ion etching of the metal layer ML, the transfer is not required. The control unit 112 controls the sputtering apparatus to form the conductive amorphous layer AL on the metal layer ML.

Next, the control unit 112 controls the transfer device 108t of the transfer module 108 to transfer an intermediate product after the formation of the conductive amorphous layer AL to a process module for performing ion etching on the conductive amorphous layer AL. It should be noted that in a case where this process module is the sputtering apparatus having the target for the conductive amorphous layer AL, the transfer is not required. The control unit 112 controls the process module to perform ion etching on the conductive amorphous layer AL.

Next, the control unit 112 controls the transfer device 108t of the transfer module 108 to transfer an intermediate product after ion etching of the conductive amorphous layer AL to a sputtering apparatus having a target for the top layer TL. It should be noted that in a case where the sputtering apparatus is the same as the process module for ion etching of the conductive amorphous layer AL, the transfer is not required. The control unit 112 controls the sputtering apparatus to form the top layer TL on the conductive amorphous layer AL. Thereby, as shown in FIG. 6, an intermediate product including the lower electrode LE is obtained.

Next, in order to sequentially form layers of the second laminate L2, that is, to form a magnetoresistive effect laminate, the control unit 112 controls the transfer device 108t of the transfer module 108 and several process modules out of the plurality of process modules 110a to 110h which are to be operated in the formation of the layers. Thereby, an intermediate product shown in FIG. 7 is obtained.

Next, the control unit 112 controls the transfer device 108t of the transfer module 108 to transfer an intermediate product including the second laminate L2 to a sputtering apparatus having a target for the upper electrode UE. The control unit 112 controls the sputtering apparatus to form the upper electrode UE on the second laminate L2. Thereby, a final product shown in FIG. 8 is obtained. It should be noted that, as described above, in order to apply heat treatment on the final product, the control unit 112 may control the transfer device 108t of the transfer module 108 to transfer the final product to a heat treatment apparatus, and then control the heat treatment apparatus to perform heat treatment. In such a manufacturing system 100, the formation of each layer of the magnetoresistive element and the planarization of the conductive amorphous layer can be continuously performed under a depressurized environment. Therefore, an apparatus (for example, a chemical mechanical polishing apparatus) that performs a planarization process under an atmospheric pressure environment is not required, and thus it is possible to achieve a reduction in the number of steps.

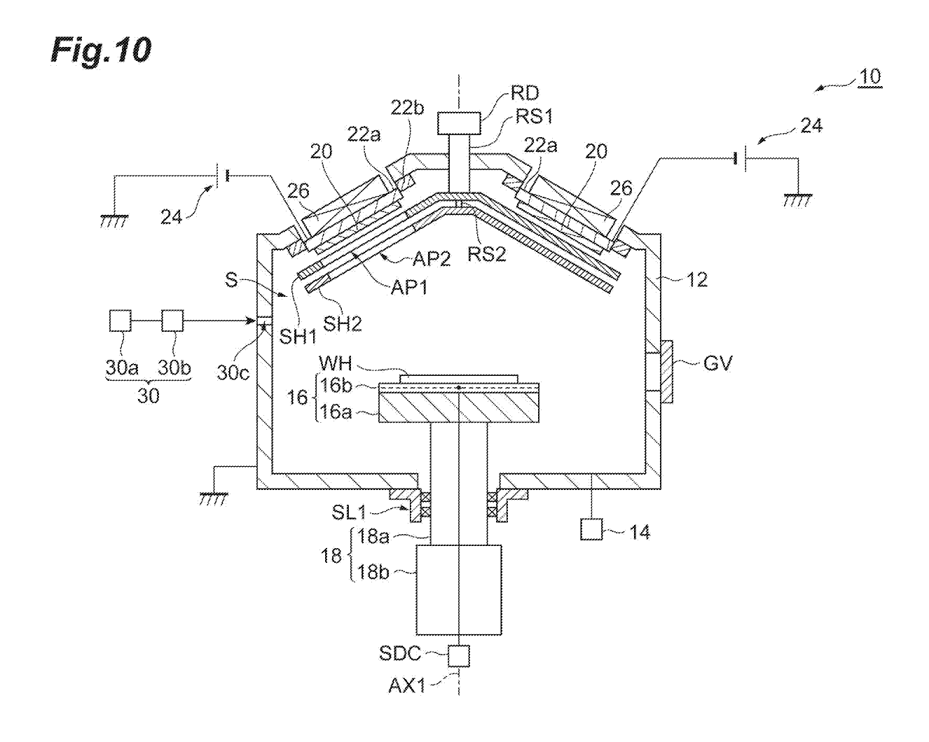

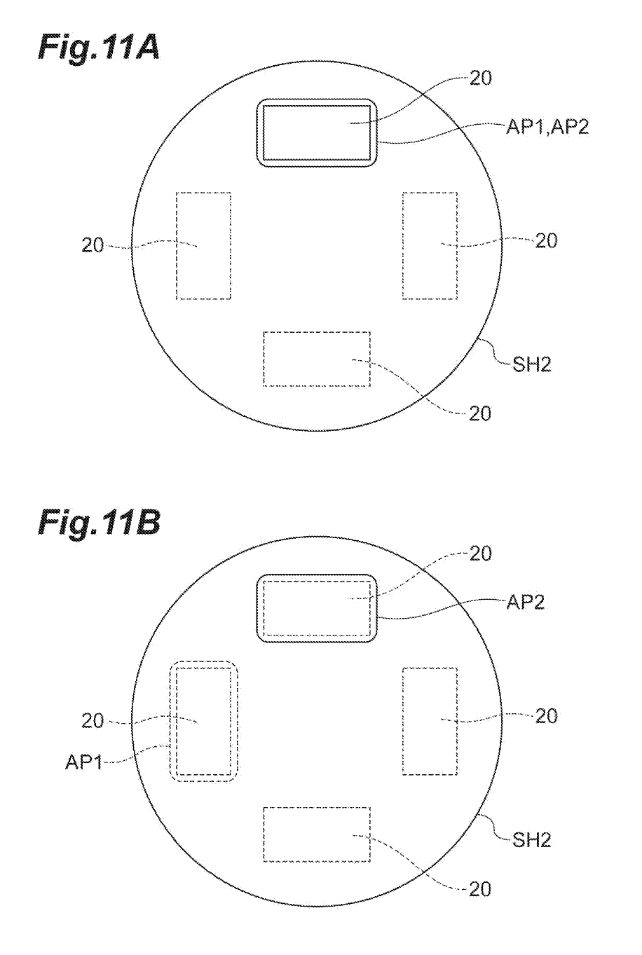

Hereinafter, the configuration of a sputtering apparatus included in the plurality of process modules 110a to 110h of the manufacturing system 100 will be illustrated. FIG. 10 is a diagram schematically illustrating an example of a sputtering apparatus capable of being used as the process module of the manufacturing system shown in FIG. 9. FIGS. 11A and 11B are plan views illustrating a shutter of the sputtering apparatus when seen from the stage side.

A sputtering apparatus 10 shown in FIG. 10 includes a processing container 12. The processing container 12 is formed of, for example, aluminum, and is connected to a ground potential. The processing container 12 provide a space S provided in inside thereof. An exhaust device 14 for depressurizing the space S is connected to the bottom of this processing container 12. The exhaust device 14 may include, for example, a cryopump and a dry pump. In addition, an opening for transferring a substrate WH is formed in a sidewall of the processing container 12. In order to open and close this opening, a gate valve GV is provided along the sidewall of the processing container 12.

A stage 16 is provided within the treatment container 12. The stage 16 may include a base portion 16a and an electrostatic chuck 16b. The base portion 16a is formed of, for example, aluminum, and has a substantially discoid shape.

The electrostatic chuck 16b is provided on the base portion 16a. The electrostatic chuck 16b includes a dielectric film and an electrode provided as an inner layer of the dielectric film. A direct-current power supply SDC is connected to the electrode of the electrostatic chuck 16b. The substrate WH (such as the base substrate BS, the intermediate products, and the like) mounted on the electrostatic chuck 16b is attracted to the electrostatic chuck 16b by electrostatic force generated by the electrostatic chuck 16b.

The stage 16 is connected to a stage driving mechanism 18. The stage driving mechanism 18 includes a shaft 18a and a driving device 18b. The shaft 18a is a substantially columnar member. The central axis of the shaft 18a is substantially coincident with an axis AX1 extending along a vertical direction. The axis AX1 is an axis passing through the center of the stage 16 in a vertical direction. The shaft 18a extends from immediately below the stage 16 through the bottom of the processing container 12 to outside of the processing container 12. A sealing member SL1 is provided between the shaft 18a and the bottom of the processing container 12. The sealing member SL1 seals a space between the bottom of the processing container 12 and the shaft 18a so that the shaft 18a can rotate and move up and down. Such a sealing member SL1 may be, for example, a magnetic fluid seal.

The stage 16 is coupled to the upper end of the shaft 18a, and the driving device 18b is connected to the lower end of the shaft 18a. The driving device 18b generates drive force for rotating and moving the shaft 18a up and down. The stage 16 rotates around the axis AX1 in association with the rotation of the shaft 18a by this drive force, and the stage 16 moves up and down in association with the movement of the shaft 18a up and down.

As shown in FIGS. 10, 11A and 11B, four targets (cathode targets) 20 are provided above the stage 16. These targets 20 are arrayed along a circular arc around the axis AX1.

The targets 20 are held by metallic holders 22a. The holders 22a are supported by the ceiling of the processing container 12 with the insulating members 22b interposed therebetween. A power source 24 is connected to the targets 20 via the holders 22a. The power source 24 applies a negative direct-current voltage to the targets 20. It should be noted that the power source 24 may be a single power source that selectively applies a voltage to a plurality of targets 20. Alternatively, the power source 24 may be a plurality of power sources which are connected to the plurality of targets 20, respectively. In addition, the power source 24 may be a high-frequency power source.

In the sputtering apparatus 10, a magnet (cathode magnet) 26 is provided outside the processing container 12 to be opposite to a corresponding target 20 with the holder 22a interposed therebetween.

In addition, the sputtering apparatus 10 includes a gas supply unit 30 that supplies a gas into the processing container 12. In an embodiment, the gas supply unit 30 includes a gas source 30a, a flow rate controller 30b, such as a mass flow controller, and a gas introduction portion 30c. The gas source 30a is a source of a gas which is excited within the processing container 12, and is a source of a rare gas (for example, Ar gas). The gas source 30a is connected to the gas introduction portion 30c via the flow rate controller 30b. The gas introduction portion 30c is a gas line for introducing a gas from the gas source 30a into the processing container 12.

When a gas is supplied from the gas supply portion 30 into the processing container 12, and a voltage is applied to the target 20 by the power source 24, the gas supplied into the processing container 12 is excited. In addition, a magnetic field is generated in the vicinity of a corresponding target 20 by the magnet 26. Thereby, plasma concentrates in the vicinity of the target 20. Positive ions in plasma collide with the target 20, and thus constitutive substances of the target 20 are emitted from the target 20. Thereby, a film is formed on the substrate WH.

In addition, a shutter SH1 and a shutter SH2 are provided between the targets 20 and the stage 16. The shutter SH1 extends so as to face the surfaces of the targets 20. The shutter SH1 has, for example, a shape extending along a conical surface around the axis AX1 as a central axis. The shutter SH2 is interposed between the shutter SH1 and the stage 16. The shutter SH2 has, for example, a shape extending along a conical surface around the axis AX1 as a central axis. The shutter SH2 is provided along the shutter SH1, and is provided to be separated from the shutter SH1.

An aperture AP1 is formed in the shutter SH1. A rotary shaft RS1 is coupled to the central portion of the shutter SH1. In addition, an aperture AP2 is formed in the shutter SH2. A rotary shaft RS2 is coupled to the central portion of the shutter SH2. The central axis of the rotary shaft RS1 and the central axis of the rotary shaft RS2 are substantially coincident with the axis AX1. That is, the rotary shaft RS1 and the rotary shaft RS2 are concentrically provided. The rotary shaft RS1 and the rotary shaft RS2 extend outside the treatment container 12, and are connected to a driving device RD. The driving device RD is configured to rotate the rotary shaft RS1 and the rotary shaft RS2 around the axis AX1 independently of each other. The shutter SH1 rotates around the axis AX1 in association with the rotation of the rotary shaft RS1, and the shutter SH2 rotates around the axis AX1 in association with the rotation of the rotary shaft RS2. Relative positions between the aperture AP1, the aperture AP2, and the target 20 change due to the rotations of the shutter SH1 and the shutter SH2. Thereby, each of the targets 20 is exposed with respect to the stage 16 through the aperture AP1 of the shutter SH1 and the aperture AP2 of the shutter SH2 (see FIG. 11A), or is shielded with respect to the stage 16 by the shutter SH1 and the shutter SH2 (see FIG. 11B).

In the state shown in FIG. 11A, a film can be formed on the substrate WH. On the other hand, in the state shown in FIG. 11B, substances which are emitted from the target 20 are shielded by the shutter SH1 and the shutter SH2, and are not deposited on the substrate WH. However, in the state shown in FIG. 11B, plasma of a rare gas is generated within the treatment container 12. Therefore, when the state shown in FIG. 11B is formed, the sputtering apparatus 10 can perform ion etching of the conductive amorphous layer AL and the metal layer ML described above. It should be noted that, in order to perform ion etching, a high-frequency power source for a high-frequency bias may be connected to the stage 16. In this case, the sputtering apparatus 10 may include a plurality of targets for forming the lower electrode LE. Thereby, in a single sputtering apparatus, the formation and ion sputtering of each layer of the lower electrode LE can be executed.

The present disclosure can be modified within the scope of the appended claims. For example, in a case where the conductive amorphous layer AL is formed by the sputtering apparatus, the sputtering apparatus may be configured to include a shutter provided with a plurality of apertures, and to simultaneously emit constituent elements of a plurality of targets toward a substrate from the plurality of targets. As a more specific example, the sputtering apparatus may be configured to form a TaZrNbB layer by emitting Ta, Zr, Nb, and B toward a substrate from four targets of a Ta target, a Zr target, a Nb target, and a B target.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of manufacturing a magnetoresistive element, comprising:
forming a first laminate on a base substrate, the first laminate configuring a lower electrode of the magnetoresistive element;
forming a second laminate on the first laminate, the second laminate being a magnetoresistive effect laminate of the magnetoresistive element; and
forming an upper electrode of the magnetoresistive element on the second laminate,
wherein said forming a first laminate includes:
forming a metal layer on the base substrate;
forming a conductive amorphous layer on the metal layer; and
performing ion etching on the conductive amorphous layer.

2. The method according to claim 1, wherein said forming a first laminate further includes performing ion etching on the metal layer before execution of said forming a conductive amorphous layer.

3. The method according to claim 1, wherein the conductive amorphous layer is made of an alloy containing three element or a four elements, and contains at least one element of boron, carbon, nitrogen, magnesium, aluminum, silicon, and titanium, and at least one element of copper, zinc, zirconium, niobium, molybdenum, hafnium, tantalum, and tungsten.

4. The method according to claim 1, wherein the conductive amorphous layer is made of CuZrAl, CuTiAl, TaZrN, or TaZrNbB.

5. The method according to claim 1, wherein the metal layer and the conductive amorphous layer are formed by sputtering.

6. A system for manufacturing a magnetoresistive element, comprising:
a transfer module including a depressurizable container, and a transfer device provided within the container for transferring a substrate;
a plurality of process modules for forming a metal layer, forming a conductive amorphous layer, ion etching, forming a magnetoresistive effect laminate, and forming an upper electrode, the plurality of process modules being connected to the transfer module; and
a control unit that controls the transfer module and the plurality of process modules,
wherein the control unit controls the transfer device and the plurality of process modules to
form the metal layer on a base substrate,
form the conductive amorphous layer on the metal layer,
perform ion etching on the conductive amorphous layer,
form the magnetoresistive effect laminate on the conductive amorphous layer, and
form the upper electrode on the magnetoresistive effect laminate.

7. The system according to claim 6, wherein the control unit further controls one process module of the plurality of process modules to perform ion etching on the metal layer before the conductive amorphous layer is formed.

8. The system according to claim 6, wherein the plurality of process modules include one or more sputtering apparatuses for forming the metal layer and forming the conductive amorphous layer.
